(19) United States
(12) Patent Application Publication
(10) Pub. No.: US 2007/0090545 A1
(43) Pub. Date: Apr. 26, 2007

(54) Semiconductor device with improved encapsulation

(76) Inventors: Brian W. Condie, Mesa, AZ (US); Mahesh K. Shah, Scottsdale, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/257,887

(22) Filed: Oct. 24, 2005

(51) Int. Cl. H01L 23/29

(52) U.S. Cl. 257/789

(57) ABSTRACT

Structure and method are provided for plastic encapsulated semiconductor devices. The encapsulation comprises a plastic binder having a dielectric constant ε_{b} and loss tangent δ_{b} and a filler mixed therewith having lower ε_{f} and/or δ_{f} so that εₘ and/or δₘ of the mix is less than ε_{b}, δ_{b}, respectively. Hollow microspheres of varied sizes are preferred fillers, desirably in the size range of about 0.3 to 300 micrometers. These should comprise at least about 50%, more preferably 60 to 70% or more of the mixture by volume so that the resulting mix has εₘ<3, preferably <2.5 and δₘ<0.005. The encapsulant mixture is placed in proximity to or on the die so that the fringing electric fields of the die, die wiring and/or die connections are exposed to a lower ε and/or δ than that of a plastic encapsulation without the filler.

The present invention generally relates to semiconductor devices, and more particularly to semiconductor devices with improved plastic encapsulation.

### BACKGROUND

Semiconductor (SC) devices are often encapsulated in molded plastic. The molded plastic surrounds and protects the semiconductor die, supports the bonding wires and external leads and imparts ruggedness and shock resistance to the device. Plastic packaged devices are widely used. FIG. 1 shows a simplified schematic cross-sectional view through prior art molded plastic package 20 containing semiconductor (SC) die 22. SC die 22 is conveniently but not essentially mounted on heatsink 23. Metal contact regions 24-1, 24-2 (collectively 24) are provided on SC die 22 to which external leads 26-1, 26-2 (collectively 26) are coupled by wirebonds or other means 25-1, 25-2 (collectively 25). Plastic encapsulant 27 is molded around SC die 22, wirebonds 25 and inner portions 28-1, 28-2 (collectively 28) of external leads 26, so that, in this example, lower surface 21 of heatsink 23 remains exposed on the lower face of package 20, but having surface 21 exposed is not essential. While plastic encapsulation, such as is illustrated in FIG. 1 and equivalents, is widely used, it suffers from a number of disadvantages and limitations well known in the art. Among these are that plastic material 27 surrounding SC die 22 and leads 25 and 28 has a significantly higher dielectric constant ε and loss tangent δ than does air or vacuum. For example, commonly used plastic encapsulants for semiconductor devices often have relative dielectric constants εₑ in the range 3.5 to 5.0 and loss tangents δₑ in the range 0.005 to 0.015 in the frequency range of interest. These are sufficient to result in significant degradation of performance, especially at high frequencies and high voltages from electrical cross-talk and coupling through plastic encapsulation 27 between various die metal regions, bonding wires and other leads, due to fringing electric field 29 (created when voltage is applied) extending into surrounding plastic encapsulant 27. The capacitive coupling and loss associated with fringing electric field 29 increase as the dielectric constant εₑ and loss tangent δₑ of encapsulant 27 increase. Such cross-talk and loss are undesirable.

In the prior art, the capacitive coupling and loss associated with this fringing electric field extending outside of the SC die has been mitigated or avoided by, for example: (i) using a Faraday shield (not shown) over the die and/or wirebonds, and/or (ii) using hollow ceramic or metal packages that provide an air or vacuum space above the sensitive die surface and around the wirebonds and inner package leads. A Faraday shield constrains the fringing fields but at the cost of additional die complexity due to the additional metal and masking layers required. A vacuum or airspace package is illustrated in FIG. 2, which shows hollow package 30 having airspace 37 surrounding die 32. Die 32 is mounted on, for example, metal or ceramic base 33 to which are attached external leads 36-1, 36-2 (collectively 36). Wirebonds or other connections 35-1, 35-2 (collectively 35) couple bonding pads 34-1, 34-2 (collectively 34) on die 32 to inner portions 38-1, 38-2 (collectively 38) of package leads 36-1, 36-2 (collectively 36). Cap 31 is placed over substrate 34, die 32, wirebonds or other connections 35 and inner portions 38 of package leads 36. Having air or vacuum space 31 around die 32 and leads 35 means that fringing electric field 39 is not in contact with any encapsulant. Therefore, there is no increase in coupling capacitance and/or loss caused by a plastic encapsulant in contract with the die surface and wirebonds and/or inner leads. The dielectric constant εₒ and loss tangent δₒ of air or vacuum are low and so cross-talk and dielectric loss are minimized. However, such air or vacuum cavity packages are significantly more expensive and often not as rugged as plastic encapsulation. Wirebonds or other connections 35 can become detached if the finished device is subjected to large acceleration forces.

Thus, there continues to be a need for improved semiconductor devices and methods that provide plastic encapsulation with reduced cross-talk and loss. Accordingly, it is desirable to provide improved semiconductor devices with plastic encapsulation having lower dielectric constant εₘ and/or loss tangent δₘ material in contact with some or all of the die surface, die leads and/or bonding wires. In addition, it is desirable that the improved plastic encapsulation materials, structures and methods allow a substantially solid structure to be formed surrounding the semiconductor die, die leads and bonding wires so as to provide a mechanically rugged package. It is further desirable that the improved device structures be achieved using fabrication technology already available on a typical semiconductor device manufacturing line so that only minor modification of the manufacturing process is required. Other desirable features and characteristics of the invention will become apparent from the subsequent detailed description and the appended claims, taken in conjunction with the accompanying drawings and the foregoing technical field and background.

### BRIEF DESCRIPTION OF THE DRAWINGS

The invention will hereinafter be described in conjunction with the following drawing figures, wherein like numerals denote like elements, and

FIG. 1 shows a simplified schematic cross-sectional view through a prior art molded plastic packaged device containing a semiconductor (SC) die;

FIG. 2 shows a simplified schematic cross-sectional view through a prior art hollow package device containing a semiconductor (SC) die;

FIG. 3 shows a simplified schematic cross-sectional view through a molded plastic packaged device containing a semiconductor (SC) die, according to an embodiment of the present invention; and

FIG. 4 show a flow chart illustrating a method according to a further embodiment of the present invention for forming a plastic encapsulated semiconductor (SC) device with lower dielectric constant and/or loss tangent material in contact with the die surface and inner leads.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

For simplicity and clarity of illustration, the drawing figures illustrate the general manner of construction, and descriptions and details of well-known features and techniques may be omitted to avoid unnecessarily obscuring the invention. Additionally, elements in the drawings figures are not necessarily drawn to scale. For example, the dimensions of some of the elements or regions in the figures may be exaggerated relative to other elements or regions to help improve understanding of embodiments of the invention.

The terms “first,” “second,” “third,” “fourth” and the like in the description and the claims, if any, may be used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “comprise,” “include,” “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus.

The terms “left,” right,” “in,” “out,” “front,” “back,” “up,” “down, “top,” “bottom,” “over,” “under,” “above,” “below” and the like in the description and the claims, if any, are used for descriptive purposes and not necessarily for describing permanent relative positions. It is to be understood that the terms so used are interchangeable under appropriate circumstances such that embodiments of the invention described herein are, for example, capable of operation in other orientations than those illustrated or otherwise described herein. The term “coupled,” as used herein, is defined as directly or indirectly connected in an electrical or non-electrical manner. As used herein, the term “lead-frame” is intended to include any supporting structure on which one or more individual or interconnected semiconductor die may be mounted, and may be metal, plastic ceramic, glass or combinations thereof. As used herein, the terms “semiconductor die” and abbreviation “SC die” are intended to include semiconductor devices of any sort and configuration, whether individual devices or complex assemblies of devices such as in integrated circuits, or any other configuration of semiconductor devices. As used herein the terms “wire bonds” and “bonding wires” are intended to include any means of electrically coupling package leads to contact regions and/or bonding pads on the SC die and not be limited merely to use of wires or the like. Non-limiting examples of other electrical coupling means are beam leads, solder bumps, metalized plastic tapes, and so forth.

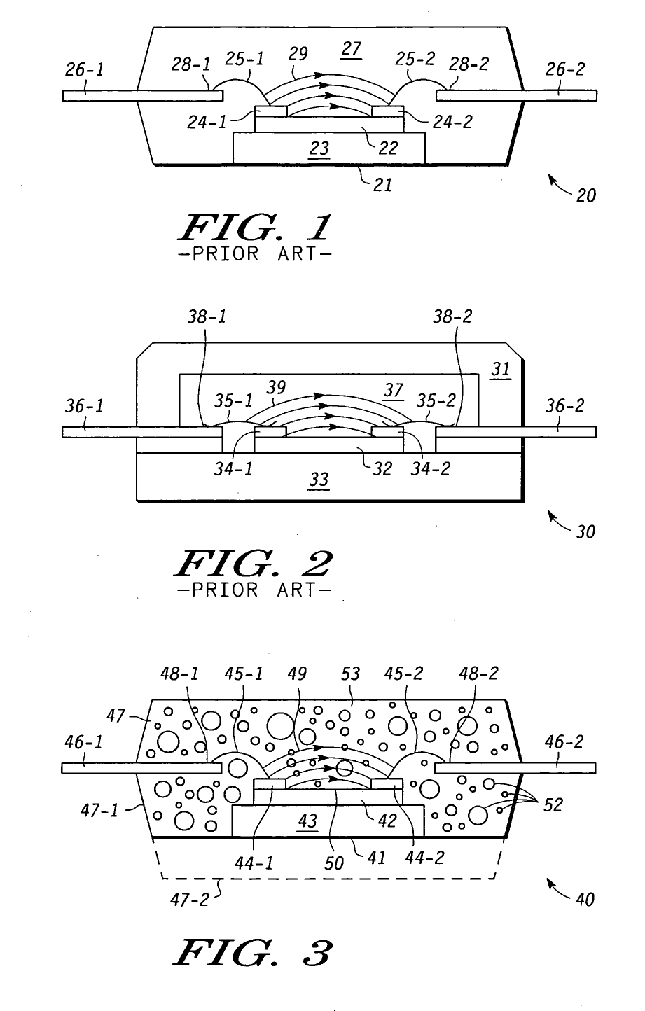

FIG. 3 shows a simplified schematic cross-sectional view through molded plastic packaged device 40 containing semiconductor (SC) die 42 surrounded by lower dielectric constant εₘ and/or lower loss tangent δₘ encapsulation 47, according to an embodiment of the present invention. Device 40 comprises SC die 42 conveniently but not essentially mounted on heat sink 43 and surrounded (except perhaps for lower surface 41 of heat sink 43) by plastic encapsulation 47. Plastic encapsulation 47 may be such that lower surface 41 of heat sink 43 is exposed as indicated by outline 47-1, or lower surface 41 may be embedded in plastic encapsulation 47 as indicated by outline 47-2. Either arrangement is useful and not important to the present invention. Die 42 has connection pads or other metalized regions 44-1, 44-2 (collectively 44) on upper surface 50 of die 42. Wirebonds or other connections 45-1, 45-2 (collectively 45) couple connection pads 44 to inner portions 48-1, 48-2 (collectively 48) of external leads 46-1, 46-2 (collectively 46), in order to provide external electrical coupling to die 42. Elements 41, 42, 43, 44, 45, 46 and 48 are analogous in function to elements 21, 22, 23, 24, 25, 26 and 28 of device 20. Fringing electric field 49 of device 40 passing through encapsulant 47. Devices 40 and 20 differ in that encapsulation 47 of device 40 has therein a significant amount of filler 52 of low dielectric constant ε_{f} and/or low loss tangent δ_{f}. When filler 52 is combined with binder or resin 53 of dielectric constant ε_{b} and loss tangent δ_{b} that makes up the remainder of encapsulation 47, this lowers the overall dielectric constant εₘ and/or loss tangent δₘ of the composite mixture making up encapsulation 47 compared to εₑ and/or δₑ of encapsulation 27 without such filler. It is important that lower dielectric constant and/or lower loss encapsulant 47 be generally in contact with or in close proximity to device surface 50, e.g., where metal pads (and other wiring traces) 44 on die 42 are located, and to wirebonds 45 and inner portions 48 of external leads 46, so as to have the maximum beneficial effect of lowering the overall dielectric constant εₘ and/or loss tangent δₘ in these locations where fringing field 49 is strongest.

A variety of low dielectric constant and low loss fillers 52 are suitable for inclusion in encapsulation 47. In general, filler 52 should be chemically stable, compatible with binder or resin 53 used in encapsulation 47 and the molding process, and available in a variety of generally microscopic sizes so as to facilitate a substantially uniform but generally random size distribution throughout the encapsulant. Further, it is desirable that including low ε_{f} and/or low δ_{f} filler 52 not result in a significant loss of strength of the overall encapsulation 47 nor produce a significant increase in its external porosity. It is desirable that a mix of filler sizes be used so that the filler 52 can be tightly packed within binder or resin 53 to fill as much space as possible (thereby minimizing the dielectric constant and loss tangent of the composite mix) with minimum impact on the overall strength of encapsulation 47. Useful materials are: finely divided styrene, Teflon®, and other light-weight plastics and glasses; low ε_{f} and/or low δ_{f} glass or ceramic fragments; and/or hollow microspheres of various materials. Hollow glass microspheres are a non-limiting example of a desirable filler material having low ε_{f} and/or low δ_{f} and are commercially available, for example, from the 3M Company of St. Paul, Minn. in a suitable range of sizes. It is desirable that the hollow microspheres or other low dielectric constant, low loss particles have lower sizes of the order of typical device feature sizes (e.g., a few micrometers or less) and maximum sizes that are, for example, not larger than about 50% percent of the minimum thickness or width of encapsulant 47 surrounding die 42 and/or lead-frame parts 43, 48 to which the die may be mounted or coupled. Stated another way, it is desirable that the particles have maximum sizes less than or equal to about 10% of the overall package thickness. The upper size limit is desirable to avoid having a fracture of one or more large microspheres in a thin region of the package cause an undesirable weak point or break in the encapsulation that might result in mechanical failure or allow moisture to enter the package or both. It is desirable that the microspheres or other particles be about ≦300 micro-meters, more conveniently about ≦100 micro-meters and preferably about ≦80 micro-meters in diameter or largest dimension. Stated another way, it is desirable that the microspheres or other particles have a size range of usefully about 0.3 to 300 micro-meters, more conveniently about 3.0 to 100 micrometers and preferably about 3.0 to 80 micro-meters, but larger or smaller ranges can also be used, depending upon the particular devices being encapsulated, the size and construction of the lead-frame, the type of filler being used and the size and construction of the finished plastic package. The amount of hollow glass microspheres (or other filler) in the mix should be as large as possible consistent with maintaining sufficient robustness and moisture resistance of the finished encapsulation. In general, the volume percentage of microspheres in the encapsulant mix should be usefully equal or greater then about 50% volume percent hollow microspheres, more conveniently equal or greater then about 60% volume percent hollow microspheres and preferably equal or greater then about 70% volume percent hollow microspheres in the encapsulant mix. These percentages are also appropriate for other low ε_{f} and/or low δ_{f} filler materials besides hollow microspheres. It is desirable that encapsulation 47 has a relative dielectric constant εₘ of less than about 3.0, more conveniently less than about 2.5 and preferably less than about 2.0. Similarly, the loss tangent δₘ of encapsulation 47 is desirably less than about 0.005. While stray fringing electric field 49 is shown in FIG. 3 as extending between die bonding pads 44-1, 44-2 having different electrical potential when device 40 is energized, this is merely for convenience of illustration and persons of skill in the art will understand that stray fringing fields can also extend at and above the surface of die 42 between other conductive regions, e.g., metal lines (not shown) on die 42, that receive different electrical potentials when used, and that all such stray fringing fields can contribute to the performance degradation described above that is mitigated by the present invention. Depending upon the choice of filler 52, either the dielectric constant εₘ or the loss tangent δₘ or both of composite or mixed encapsulation 47 may be reduced compared to εₑ and/or δₑ of encapsulation 27 without filler 52. Reducing the dielectric constant εₘ reduces the cross-talk. Reducing the loss tangent δₘ reduces the power loss. Either result is beneficial. It is desirable that both εₘ and δₘ be reduced but this is not essential and the expressions “low εₘ and/or δₘ” and “lower εₘ and/or εₘ” are intended to include having either εₘ or δₘ, or both εₘ and δₘ, reduced compared to εₑ and/or δₑ of an encapsulation without filler 52.

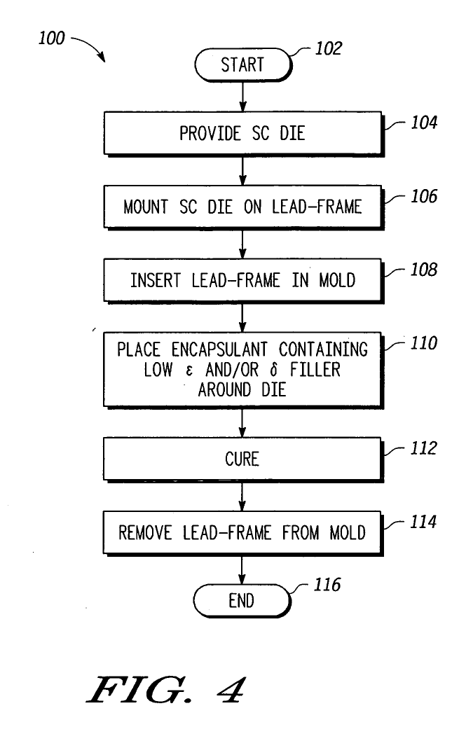

FIG. 4 show a flow chart, illustrating method 100 for forming a plastic encapsulated semiconductor (SC) device with material having lower dielectric constant εₘ and/or lower loss tangent δₘ in contact with the die surface and inner leads. Method 100 begins with START 102 and initial step 104 wherein the SC die or device is provided or obtained using means well known in the art. In step 106 the SC die or device is mounted on a lead-frame or other support. As used herein, the words “lead-frame” are intended to include other forms of die supports besides metal lead frames, as for example, and not intended to be limiting, ceramic bases, plastic bases, composite assemblies and combinations thereof. In step 108, the lead-frame containing the SC die is inserted in a plastic encapsulation mold so that the region surrounding the die and any bonding wires or other connections intended to be protected by the encapsulant are located in a cavity. In general, the cavity usually has approximately the shape of the desired finished device package. The mold may be a small book mold used for small device runs, or a large multi-cavity mold with dozens to hundreds of cavities that is clamped in a hydraulic press, but in general the type of mold is not critical to the present invention other than it must be able to handle encapsulation 47 containing low dielectric constant ε_{f} and/or low loss tangent δ_{f} filler material 52 described above. In step 110, the encapsulant containing the low ε_{f} and/or δ_{f} filler is transferred and/or injected or otherwise placed in the mold to fill the cavities surrounding the SC die and associated leads. Means and methods for accomplishing this are well known in the art. The resin used as carrier and binder 53 for filler 52 may be of a thermo-setting type or a catalyzed type or other suitable type according to the desires of the package designer and the environmental specifications for the finished device. Either arrangement is useful. In step 112, the encapsulation containing the low ε_{f} and/or δ_{f} filler is cured under the appropriate conditions depending upon the type of resin or binder and filler being employed. In generally, such cure routines are either well known or easily determinable for any particular resin-filler combination. Persons of skill in the art understand how to do this. When cure is substantially complete or at least advanced sufficiently so that the lead-frame with encapsulation 47 around die 42 can be safely handled, then in step 114, the mold is opened and the lead-frame with molded encapsulation 47 removed from the mold. Subsequent processing such as post mold cure, and to trim and form the lead frame and/or package are conventional and well known in the art and will vary depending upon the nature of the lead frame and shape of the plastic package being employed. In some cases the die heat sink is exposed, in other cases, it is contained entirely within plastic encapsulation 47, depending upon the device needs. Following step 114, method 100 proceeds to END 116.

According to a first embodiment, there is provided a semiconductor device, comprising, a die support, a semiconductor die mounted on a portion of the die support, a plastic encapsulation on at least part of the die support and the die, wherein the plastic encapsulation comprises at least two components, a plastic binder having a dielectric constant ε_{b} and loss tangent δ_{b}, and a filler material having a lower dielectric constant ε_{f} and/or lower loss tangent δ_{f}, mixed with the plastic binder to form the plastic encapsulation having combined dielectric constant εₘ and loss tangent δₘ, such that either εₘ<ε_{b} or δₘ<δ_{b} or both εₘ<ε_{b} and δₘ<δ_{b}. According to a further embodiment, the filler material comprises hollow microspheres. According to a still further embodiment, the hollow microspheres have sizes less than about 300 micrometers diameter. According to a yet further embodiment, the hollow microspheres comprise at least about 50 percent by volume of the plastic encapsulation. According to an additional embodiment, the plastic encapsulation, has a dielectric constant εₘ less than about 3 or loss tangent δₘ less than about 0.005, or both.

According to a second embodiment, there is provided a plastic encapsulated semiconductor device, comprising, a semiconductor die, a plastic encapsulation covering one or more faces of the die, wherein the plastic encapsulation comprises a binder having dielectric constant ε_{b} and loss tangent δ_{b} and a filler material mixed together so as to have a resulting dielectric constant εₘ and loss tangent δₘ such that either εₘ<ε_{b} or δₘ<δ_{b} or both εₘ<ε_{b} and δₘ<δ_{b}. According to a further embodiment, the filler material comprises a low density plastic. According to a still further embodiment, the filler material comprises hollow microspheres. According to a yet further embodiment, the filler comprises hollow microspheres that are between about 0.3 and 300 micro-meters in diameter. According to an additional embodiment, the filler comprises glass, ceramic or plastic particles that are between about 0.3 and 100 micro-meters in their largest dimension. According to a yet additional embodiment, the plastic encapsulation, has a dielectric constant εₘ less than about 3 or loss tangent δₘ less than about 0.005, or both. According to a still additional embodiment, the plastic encapsulation, has a dielectric constant εₘ less than about 2.5. According to a yet still additional embodiment, the particles comprise at least 50 percent by volume of the plastic encapsulation. According to a still yet additional embodiment, the particles comprise at least 70 percent by volume of the plastic encapsulation.

According to a third embodiment, there is provided a method of encapsulating a semiconductor die, comprising, mounting the die on a support, placing the support with the die in a mold suitable for plastic encapsulation, wherein the die is located in a cavity in the mold, placing a plastic encapsulant in the cavity of the mold to substantially encapsulate the semiconductor die, wherein the encapsulant comprises a mixture of a plastic resin having a dielectric constant ε_{b} and loss tangent δ_{b} and a filler material that imparts to the mixture a dielectric constant εₘ and loss tangent δₘ, wherein either εₘ<ε_{b} or δₘ<δ_{b} or both εₘ<ε_{b} and δₘ<δ_{b}. According to an additional embodiment, the method further comprises curing the plastic encapsulant in the mold. According to a still additional embodiment, the step of placing the plastic encapsulant in the cavity of the mold comprises, placing a plastic encapsulant having a filler comprising hollow glass, ceramic, plastic microspheres or a combination thereof, whose sizes are less than about 300 micrometers. According to a yet additional embodiment, the step of placing the plastic encapsulant in the cavity of the mold comprises, placing a plastic encapsulant having at least 50 percent by volume of the filler. According to a yet still additional embodiment, the step of placing the plastic encapsulant in the cavity of the mold comprises, placing a plastic encapsulant having εₘ<3. According to a still yet additional embodiment, the step of placing the plastic encapsulant in the cavity of the mold comprises, placing a plastic encapsulant having εₘ<2.5.

While at least one exemplary embodiment has been presented in the foregoing detailed description, it should be appreciated that a vast number of variations exist. For example, a wide variety of low dielectric constant and/or low loss fillers may be used in conjunction with various resins as carriers and binders. Persons of skill in the art will understand that the principals taught herein also apply to such variations. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A semiconductor device, comprising:
a die support;
a semiconductor die mounted on a portion of the die support;
a plastic encapsulation on at least part of the die support and the die;
wherein the plastic encapsulation comprises at least two components:
a plastic binder having a dielectric constant ε_{b}and loss tangent δ_{b}; and
a filler material having a lower dielectric constant ε_{f} and/or lower loss tangent δ_{f}, mixed with the plastic binder to form the plastic encapsulation having combined dielectric constant εₘ and loss tangent δₘ, such that either εₘ<ε_{b} or δₘ<δ_{b} or both εₘ<ε_{b} and δₘ<δ_{b}.

2. The device of claim 1, wherein the filler material comprises hollow micro spheres.

3. The device of claim 2, wherein the hollow microspheres have sizes less than about 300 micrometers diameter.

4. The device of claim 2, wherein the hollow microspheres comprise at least about 50 percent by volume of the plastic encapsulation.

5. The device of claim 1, wherein the plastic encapsulation, has a dielectric constant εₘ less than about 3 or loss tangent δₘ less than about 0.005, or both.

6. A plastic encapsulated semiconductor device, comprising:
a semiconductor die;
a plastic encapsulation covering one or more faces of the die, wherein the plastic encapsulation comprises a binder having dielectric constant ε_{b} and loss tangent δ_{b} and a filler material mixed together so as to have a resulting dielectric constant δₘ and loss tangent δₘ such that either εₘ<ε_{b} or δₘ<δ_{b} or both εₘ<ε_{b} and δₘ<δ_{b}.

7. The device of claim 6, wherein the filler material comprises a low density plastic.

8. The device of claim 6, wherein the filler material comprises hollow micro spheres.

9. The device of claim 8, wherein the filler comprises hollow microspheres that are between about 0.3 and 300 micro-meters in diameter.

10. The device of claim 6, wherein the filler comprises glass, ceramic or plastic particles that are between about 0.3 and 100 micro-meters in their largest dimension.

11. The device of claim 6, wherein the plastic encapsulation, has a dielectric constant εₘ less than about 3 or loss tangent δₘ less than about 0.005, or both.

12. The device of claim 11, wherein the plastic encapsulation, has a dielectric constant εₘ less than about 2.5.

13. The device of claim 10, wherein the particles comprise at least 50 percent by volume of the plastic encapsulation.

14. The device of claim 13, wherein the particles comprise at least 70 percent by volume of the plastic encapsulation.

15. A method of encapsulating a semiconductor die, comprising:
mounting the die on a support;
placing the support with the die in a mold suitable for plastic encapsulation, wherein the die is located in a cavity in the mold;
placing a plastic encapsulant in the cavity of the mold to substantially encapsulate the semiconductor die, wherein the encapsulant comprises a mixture of a plastic resin having a dielectric constant ε_{b} and loss tangent δ_{b} and a filler material that imparts to the mixture a dielectric constant εₘ and loss tangent δₘ, wherein either εₘ<ε_{b} or δₘ<δ_{b} or both εₘ<ε_{b} and δₘ<δ_{b}.

16. The method of claims 15, further comprising, curing the plastic encapsulant in the mold.

17. The method of claim 15, wherein the step of placing the plastic encapsulant in the cavity of the mold comprises, placing a plastic encapsulant having a filler comprising hollow glass, ceramic, plastic microspheres or a combination thereof, whose sizes are less than about 300 micrometers.

18. The method of claim 15, wherein the step of placing the plastic encapsulant in the cavity of the mold comprises, placing a plastic encapsulant having at least 50 percent by volume of the filler.

19. The method of claim 15, wherein the step of placing the plastic encapsulant in the cavity of the mold comprises, placing a plastic encapsulant having εₘ<3.

20. The method of claim 19, wherein the step of placing the plastic encapsulant in the cavity of the mold comprises, placing a plastic encapsulant having δₘ<0.005.
